(19) United States
(12) Patent Application Publication
(10) Pub. No.: US 2009/0014804 A1
(43) Pub. Date: Jan. 15, 2009

(54) MISFET, SEMICONDUCTOR DEVICE HAVING THE MISFET AND METHOD OF MANUFACTURING THE SAME

(75) Inventor: Masashi SHIMA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/238,799

(22) Filed: Sep. 26, 2008

Related U.S. Application Data
(63) Continuation of application No. PCT/JP2006/306427, filed on Mar. 29, 2006.

(30) Foreign Application Priority Data
Mar. 29, 2006 (JP) 2008-511877

(51) Int. Cl. H01L 29/78; H01L 21/336

(52) U.S. Cl. 257/368; 438/585; 257/E29.255; 257/E21.409

(57) ABSTRACT

To solve the problem, a MISFET covered with an insulating film which generates stress is provided. The MISFET including a gate insulating film; a gate electrode disposed on the gate insulating film, the gate electrode including a polysilicon portion and a silicide portion; and a source/drain disposed adjacent to the gate electrode, in which the ratio between the polysilicon portion and the silicide portion is determined depending on a strain for enhancing the driving capability of the MISFET, the strain being generated on the basis of the stress through the gate electrode in a channel region of the MISFET.

### CROSS REFERENCE TO RELATED APPLICATION

This application is based upon and claims the benefit of priority from the prior Japanese Patent Application NO. 2008-511877 filed on Mar. 29, 2006, the entire contents of which are incorporated herein by reference.

### BACKGROUND

1. Field

The embodiments discussed herein are related to a semiconductor device having the MISFET in which strain is caused in a channel region by using the stress so that drive current is increased, and a method for manufacturing the same.

2. Description of the Related Art

When strain is caused by applying stress in a certain direction to a MISFET, the mobility of carriers which are responsible for conductivity in the MISFET is increased, thus improving the characteristics of the MISFET.

Consequently, various techniques for applying stress to a MISFET have been under study. In one of the techniques, stress is applied to a MISFET by using a contact etching stop film which is formed so as to cover the MISFET.

In the technique of applying stress to a MISFET by using a contact etching stop film, the amount of stress can be controlled by controlling the thickness of the contact etching stop film. However, it is not possible to partially control the direction of stress applied by the contact etching stop film in the contact etching stop film.

Here, in order to improve the characteristics of an N-type MISFET or a P-type MISFET, it is necessary to apply stress in a certain direction. Consequently, when the direction of stress applied by the contact etching stop film is different from the direction of stress in which the characteristics of the MISFET are improved, the characteristics of the MISFET are not improved.

Furthermore, the direction of stress to be applied to a channel region to improve the characteristics is different between an N-type MISFET and a P-type MISFET. Consequently, depending on the technique of applying stress to a MISFET using a contact etching stop film, it is not possible to simultaneously improve the characteristics of the N-type MISFET and the characteristics of the P-type MISFET.

The reason for this is that in the ordinary structure of a MISFET, stress generated by a contact etching stop film is directly transmitted to a channel region of the MISFET.

Consequently, a structure has been proposed in which a contact etching stop film which generates compressive stress is deposited on a P-type MISFET and a contact etching stop film which generates tensile stress is deposited on an N-type MISFET (for example, Patent Document 1: International Publication No. WO2002/043151)

According to Patent Document 1, in order to obtain the structure described above, the following steps are carried out. First, a step of depositing the contact etching stop film which generates compressive stress is carried out. Next, a step of removing the contact etching stop film which generates compressive stress lying on the N-type MISFET is carried out. Then, a step of newly depositing the contact etching stop film which generates tensile stress is carried out. Thus, the contact etching stop film which generates compressive stress is formed on the P-type MISFET, and the contact etching stop film which generates tensile stress is formed on the N-type MISFET.

### SUMMARY

According to one aspect of embodiments, a semiconductor device having a MISFET is provided. The MISFET covered with an insulating film which generates stress, the MISFET including a gate insulating film disposed on a semiconductor substrate; a gate electrode disposed on the gate insulating film, the gate electrode including a polysilicon portion and a silicide portion; a source disposed adjacent to one side of the gate electrode; and a drain disposed adjacent to the other side of the gate electrode, in which the ratio between the polysilicon portion and the silicide portion is determined depending on a strain for enhancing the driving capability of the MISFET, the strain being generated on the basis of the stress generated by the insulating film through the gate electrode in a channel region of the MISFET under the gate electrode.

### BRIEF DESCRIPTION OF THE DRAWINGS

FIG. 1 is a table showing the direction of stress, i.e., the direction of strain, applied to a channel region of an N-type MISFET, which is most suitable for improving a drive current of the N-type MISFET, and the direction of stress, i.e., the direction of strain, applied to a channel region of a P-type MISFET, which is most suitable for improving a drive current of the P-type MISFET.

FIGS. 2A and 2B show a cross-sectional view of a MISFET covered with a contact etching stop film and a graph showing the strains generated in channel regions of MISFETs.

FIGS. 3A to 3D show a cross-sectional view of a MISFET according to Embodiment 1, and graphs showing the strains generated in channel regions of MISFETs according to Embodiment 1.

FIGS. 4A to 4D show a cross-sectional view of another MISFET according to Embodiment 1, and graphs showing the strains generated in channel regions of MISFETs according to Embodiment 1.

FIGS. 5A to 5D show cross-sectional views of semiconductor devices according to Embodiment 2, and graphs showing the ratio between the polysilicon portion and the silicide portion constituting the gate electrode of each of the N-type MISFET and the P-type MISFET.

FIGS. 6A to 6D show cross-sectional views of semiconductor devices according to Embodiment 3, and graphs showing the ratio between the polysilicon portion and the silicide portion constituting the gate electrode of each of the N-type MISFET and the P-type MISFET.

FIGS. 7A to 7D are cross-sectional views showing the steps in a method for manufacturing the semiconductor device shown in FIG. 5A or 5C.

FIGS. 8A to 8D are cross-sectional views showing the steps in a method for manufacturing the semiconductor device shown in FIG. 6A or 6C.

### DESCRIPTION OF THE PREFERRED EMBODIMENTS

Embodiments 1, 2, 3, 4, and 5 will be described below.

### Embodiment 1

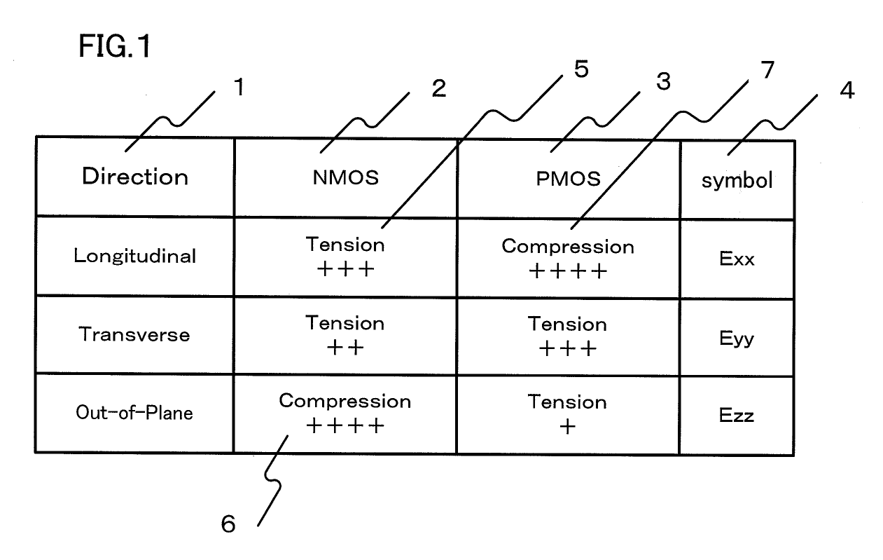

Embodiment 1 relates to a MISFET which has a structure in which stress generated by a contact etching stop film is relaxed or enhanced and transmitted to a channel region of the MISFET, and in which the current-driving capability is improved. Embodiment 1 will be described with reference to FIGS. 1, 2A, 2B, 3A to 3D, and 4A to 4D.

FIG. 1 is a table showing the direction of stress, i.e., the direction of strain, applied to a channel region of an N-type MISFET, which is most suitable for improving a drive current of the N-type MISFET, and the direction of stress, i.e., the direction of strain, applied to a channel region of a P-type MISFET, which is most suitable for improving a drive current of the P-type MISFET.

With respect to the table of FIG. 1, column 1 of Direction, column 2 of NMOS, column 3 of PMOS, column 4 of symbol, Tension +++5, Compression ++++6, and field 7 showing Compression ++++ will be described below.

In column 1 of Direction, the direction of stress or strain generated by stress is described. The direction of stress or strain includes the Longitudinal direction (X direction: direction in which a source and a drain are connected), the Transverse direction (Y direction: direction vertical to the direction in which the source and the drain are connected), and the Out-Of-Plane direction (Z direction, namely, direction vertical to a semiconductor surface).

In column 2 of NMOS, the direction of stress which is most suitable for improving a drive current of an N-type MISFET is described.

With respect to the Longitudinal direction, strain due to Tension is the most suitable strain, and the mark “+++” subsequent thereto is an index representing the degree of improvement in drive current under a constant amount of strain. That is, as the number of “+”s increases, the degree of contribution to improvement in drive current increases.

Consequently, “Tension +++5” indicates that, when strain is applied by tensile force in the source/drain direction, the degree of contribution to improvement in drive current is slightly larger than medium.

Similarly, with respect to the Transverse direction, “Tension ++” is described under column 2 of NMOS, indicating that, with respect to the Transverse direction, strain due to Tension is the most suitable strain, and the degree of contribution to improvement in drive current is slightly smaller than medium. Furthermore, with respect to the Out-Of-Plane direction, “Compression ++++6” is described under column 2 of NMOS, indicating that, with respect to the Out-Of-Plane direction, strain due to Compression is the most suitable strain, and the degree of contribution to improvement in drive current is large.

In column 3 of PMOS, the direction of stress which is most suitable for improving a drive current of a P-type MISFET is described.

With respect to the Longitudinal direction, “Compression ++++” is described, indicating that strain due to Compression is the most suitable strain, and the degree of contribution to improvement in drive current is large.

Furthermore, with respect to the Transverse direction, “Tension +++” is described under column 3 of PMOS. That is, with respect to the Transverse direction, strain due to Tension is the most suitable strain, and the degree of contribution to improvement in drive current is slightly larger than medium. Furthermore, with respect to the Out-Of-Plane direction, “Tension +” is described under column 3 of PMOS, indicating that, with respect to the Out-Of-Plane direction, strain due to Tension is the most suitable strain, and the degree of contribution to improvement in drive current is small.

In this embodiment, in order to improve the drive current of a MISFET, it is necessary to set the Longitudinal direction (X direction: direction in which a source and a drain are connected) to agree with the <110> direction of the semiconductor substrate.

The reason for this is that the band structure in silicon crystal is changed by application of strain, and the effective mobility of conduction carriers in an inversion layer of the MISFET improves, resulting in improvement in the drive current of the MISFET. Furthermore, if strain is applied in a wrong direction, the effective mobility of conduction carriers decreases.

Furthermore, the directions of stress, which cause strain that is most suitable for improving the drive current of the MISFET, described in column 2 of NMOS and column 3 of PMOS are described referring to Non-Patent Document: S. E. Thompson et al., IEEE Trans. Elec. Dev, pp. 1790-1797, November 2004.

In column 4 of symbol, symbol Exx represents the strain in the Longitudinal direction (X direction: direction in which a source and a drain are connected), symbol Eyy represents the strain in the Transverse direction (Y direction: direction vertical to the direction in which the source and the drain are connected), and symbol Ezz represents the strain in the Out-Of-Plane direction (Z direction, namely, direction vertical to a semiconductor surface).

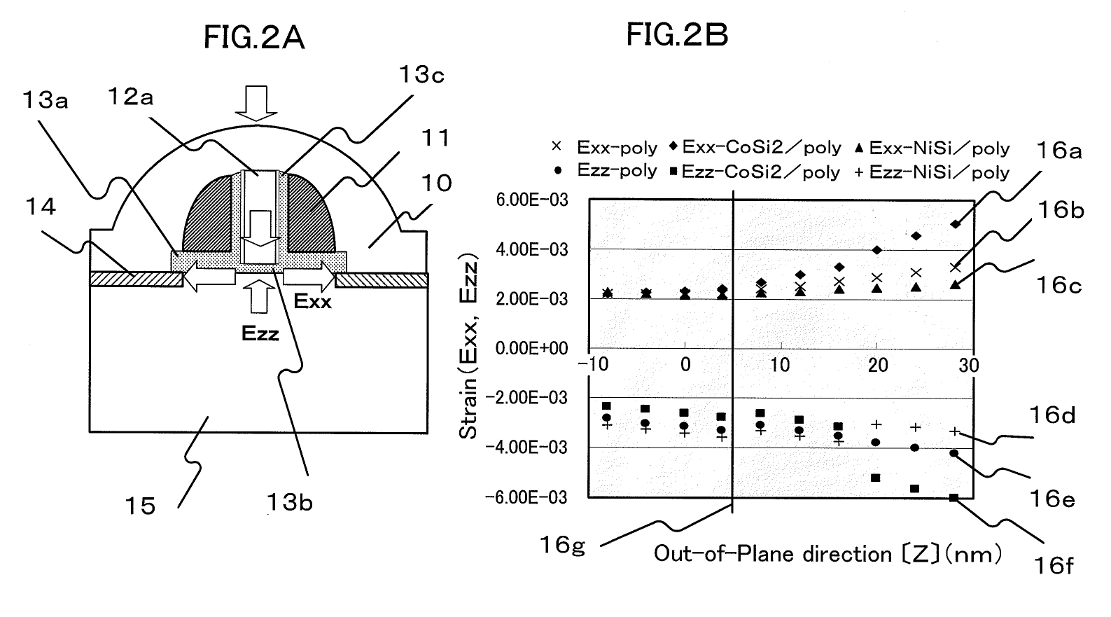

FIGS. 2A and 2B show a cross-sectional view of a MISFET covered with a contact etching stop film and a graph showing the strains generated in channel regions of MISFETs.

Referring to FIG. 2A, a MISFET covered with a contact etching stop film is disposed on a principal surface of a semiconductor substrate 15 and covered with a contact etching stop film 10 which causes stress in the MISFET. Furthermore, the MISFET covered with the contact etching stop film 10 includes a gate insulating film 13b, an oxide film 13a under a sidewall, a gate electrode 12a composed of silicide or polysilicon, a sidewall 11 disposed on a side surface of the gate electrode 12a through an oxide film 13c on the sidewall of the gate electrode, and source/drain regions 14 disposed adjacent to both sides of the gate electrode 12a.

FIG. 2B is a graph showing the strain generated in the vicinity of a gate electrode by the stress from a contact etching stop film 10 in the structure of each MISFET covered with the contact etching stop film 10, the results being obtained by simulation. In FIG. 2B, the vertical axis represents the strain, in which a strain in the compression direction is considered as a negative strain, and a strain in the tension direction is considered as a positive strain. Furthermore, a strain is defined as a quotient obtained by dividing an extended length or a compressed length by the original length, and thus the strain is a nondimensional number. Furthermore, in FIG. 2B, the horizontal axis represents the position of the MISFET in a direction vertical to the surface of the semiconductor in a range from −10 nm to 30 nm, where the interface between the gate electrode 12a and the gate insulating film 13b is the original, the height direction of the gate electrode 12a is positive, and the direction downward from the gate insulating film 13b is negative.

FIG. 2B is a graph showing, by simulation, the strain in the Longitudinal direction (X direction: direction in which a source and a drain are connected), i.e., Exx, and the strain in the Out-Of-Plane direction (Z direction, namely, direction vertical to the semiconductor surface), i.e., Ezz, in the case where polysilicon, nickel silicide, or cobalt silicide is used as a material for the gate electrode. In FIG. 2B, crosses and a line 16b represented by the crosses represent strains Exx in the case where polysilicon is used as the material for the gate electrode, and solid circles and a line 16e represented by the solid circles represent strains Ezz in the case where polysilicon is used as the material for the gate electrode. In FIG. 2B, solid diamonds and a line 16a represented by the solid diamonds represent strains Exx in the case where cobalt (Co) silicide is used as the material for the gate electrode, and solid squares and a line 16f represented by the solid squares represent strains Ezz in the case where cobalt (Co) silicide is used as the material for the gate electrode. In FIG. 2B, solid triangles and a line 16c represented by the solid triangles represent strains Exx in the case where nickel (Ni) silicide is used as the material for the gate electrode, and pluses and a line 16d represented by the pluses represent strains Ezz in the case where nickel (Ni) silicide is used as the material for the gate electrode. In FIG. 2B, a solid line 16g vertically intersecting the horizontal axis at a position of 5 nm represents the interface between the gate insulating film and the silicon substrate, namely, the surface of the channel.

The hardness is high in the order of cobalt (Co) silicide, polysilicon, and nickel (Ni) silicide. In the simulation to determine the strains described above, the Young's modulus of cobalt (Co) silicide is 100 GPa, the Young's modulus of polysilicon is 160 GPa, and the Young's modulus of nickel (Ni) silicide is 200 GPa.

Furthermore, the width of the gate electrode 12a is 40 nm, the height of the gate electrode 12a is 76 nm, the width of the sidewall 11 is 50 nm, and the thickness of the contact etching stop film 10 on the MISFET is 80 nm. Furthermore, the contact etching stop film 10 is a film which imparts tensile stress, namely, a contact etching stop film having tensile stress. Note that the contact etching stop film 10 can be formed to be a film which imparts tensile stress or a film which imparts compressive stress depending on the conditions for film formation.

According to FIG. 2B, when the line 16a represented by the solid diamonds, the line 16b represented by the crosses, and the line 16c represented by the solid triangles are compared, the material having lower Young's modulus, namely, higher hardness, has larger positive strain Exx in the direction in which the source region and the drain region are connected. Consequently, even in the vicinity of the interface between the gate electrode 12a and the gate insulating film 13b, i.e., the origin, the material having lower Young's modulus has larger strain Exx in the direction in which the source and the drain are connected. Furthermore, as is evident from the graph, as the position vertical to the semiconductor surface moves toward the positive direction, with the interface between the gate electrode 12a and the gate insulating film 13b being the origin, the strain in the tensile direction (positive strain) increases.

On the other hand, when the line 16d represented by the pluses, the line 16e represented by the solid circles, and the line 16f represented by the solid squares are compared, with respect to the strain Ezz in the direction vertical to the semiconductor surface, in a region exceeding 20 nm in the direction vertical to the semiconductor surface, the strain in the compressive direction (negative strain) is high in the order of cobalt (Co) silicide, polysilicon, and nickel (Ni) silicide. However, in the vicinity of the origin in the direction vertical to the semiconductor surface, the strain in the compressive direction (negative strain) is low in the order of cobalt (Co) silicide, polysilicon, and nickel (Ni) silicide.

As is evident from the above, on the basis of the compressive stress of the contact etching stop film 10, Exx in the tensile direction (the strain in the direction in which the source region and the drain region are connected) and Ezz in the compressive direction (the strain in the direction vertical to the semiconductor substrate) are imparted through the gate electrode 12a to the interface between the gate electrode 12a and the gate insulating film 13b, namely, the channel region under the gate electrode 12a.

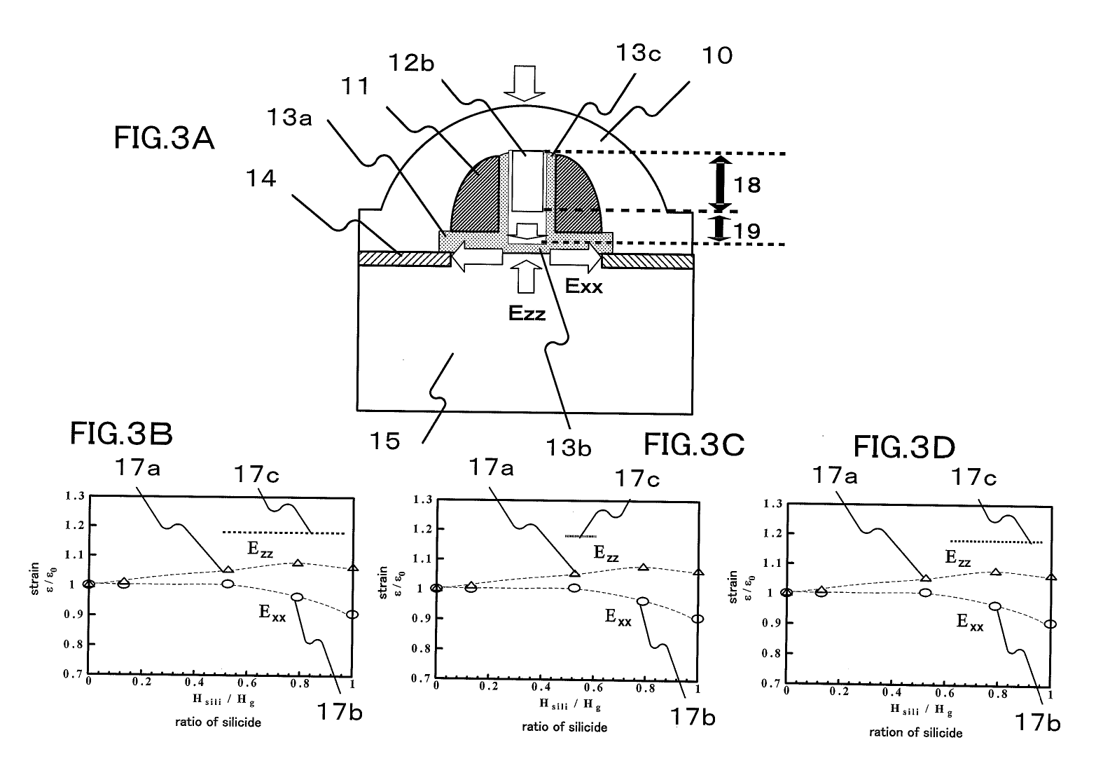

FIGS. 3A to 3D show a cross-sectional view of a MISFET according to Embodiment 1, and graphs showing the strains generated in channel regions of MISFETs according to Embodiment 1.

FIG. 3A is a cross-sectional view of a MISFET according to Embodiment 1, the MISFET being covered with a contact etching stop film 10 which generates tensile stress, the cross-sectional view showing a gate electrode structure which controls Exx (strain in the direction in which a source region and a drain region are connected) and Ezz (strain in the direction vertical to the semiconductor substrate) generated in a channel region.

The MISFET according to Embodiment 1 is disposed on a principal surface of a semiconductor substrate 15 and covered with a contact etching stop film 10 which causes tensile stress in the MISFET. Furthermore, the MISFET shown in FIG. 3A includes a gate insulating film 13b, an oxide film 13a under a sidewall, a gate electrode 12b having a nickel (Ni) silicide portion 18 and a polysilicon portion 19 which are arranged at a predetermined ratio, a sidewall 11 disposed on a side surface of the gate electrode 12b through an oxide film 13c on the sidewall of the gate electrode, and source/drain regions 14 disposed adjacent to both sides of the gate electrode 12b. The same components as those in FIG. 2A are designated by the same reference numerals. However, the gate electrode 12b is different from the gate electrode 12a (composed of polysilicon or silicide) in that the gate electrode 12b has the polysilicon 19 and the nickel silicide 18 at a predetermined ratio.

Since the MISFET is stretched from both sides by the contact etching stop film 10 which generates tensile stress, compressive stress occurs from the height direction in the gate electrode 12b.

FIG. 3B is a graph which shows the relationship between each of Exx (strain in the direction in which the source region and the drain region are connected) and Ezz (strain in the direction vertical to the semiconductor substrate) generated in the channel region and the ratio of nickel (Ni) silicide in the gate electrode 12b in the case where the MISFET of FIG. 3A is an N-type MISFET. FIG. 3B also shows strain for enhancing the driving capability of the MISFET, the strain being caused through the gate electrode in the channel region of the MISFET under the gate electrode on the basis of the stress generated by the insulating film, and a range of the ratio of silicide in response to the strain in the case where the MISFET of FIG. 3A is an N-type MISFET.

Furthermore, FIG. 3B shows open triangles 17a and a curve connecting the open triangles 17a, open circles 17b and a curve connecting the open circles 17b, and a dotted line 17c representing a range of the ratio of silicide.

The horizontal axis of the graph of FIG. 3B represents the ratio of the length in the height direction of the silicide portion to the length in the height direction of the entire gate electrode 12b. Furthermore, the vertical axis of the graph of FIG. 3B represents the ratio of the strain in the case where the gate electrode 12b is composed of polysilicon and silicide to the strain in the case where the gate electrode 12b is entirely composed of polysilicon.

The open triangles 17a and the curve connecting the open triangles 17a represent changes in strain relative to the ratio of silicide for the strain (Ezz) in the direction vertical to the semiconductor substrate. According to the open triangles 17a and the curve connecting the open triangles 17a, as the ratio of silicide increases from 0 to 0.8, the ratio of strain increases from 1.0 to 1.1. The reason for this is that, in the case where the gate electrode 12b is composed of nickel (Ni) silicide, Ezz (strain in the Z direction) increases compared with the case where the gate electrode 12b is composed of polysilicon only as shown in FIG. 2B, and consequently, as the ratio of nickel (Ni) silicide increases in the gate electrode 12b, Ezz (strain in the Z direction) is considered to increase. Furthermore, even if the ratio of silicide increases from 0.8 to 1.0, a ratio of strain of about 1.1 is maintained.

The open circles 17b and the curve connecting the open circles 17b represent changes in strain relative to the ratio of silicide for the strain (Exx) in the direction in which the source and the drain are connected. According to the open circles 17b and the curve connecting the open circles 17b, even if the ratio of silicide increases from 0 to 0.5, the ratio of strain is maintained to be 1.0. As the ratio of silicide increases from 0.5 to 1.0, the ratio of strain changes from 1.0 to 0.9. The reason for this is that, in the case where the gate electrode 12b is composed of nickel (Ni) silicide, Exx (strain in the X direction) decreases compared with the case where the gate electrode 12b is composed of polysilicon only as shown in FIG. 2B, and consequently, as the ratio of nickel (Ni) silicide increases in the gate electrode 12b, Exx (strain in the X direction) is considered to decrease.

The dotted line 17c representing a range of the ratio of silicide shows the range of the ratio of silicide in response to the strain which increases the current-driving capability of the N-type MISFET of FIG. 3B. That is, in the N-type MISFET of FIG. 3B, the ratio of nickel (Ni) silicide in the gate electrode 12b is limited to a range of 0.5 to 1.0.

The reason for the increase in the current-driving capability of the MISFET will be described below. First, according to the table of FIG. 1, in the channel region of the N-type MISFET, the strain due to compression in the direction vertical to the semiconductor substrate largely increases the driving capability of the N-type MISFET. Consequently, as the ratio of nickel (Ni) silicide increases, the strain increases, and the driving capability of the MISFET increases. On the other hand, in the channel region of the N-type MISFET, the strain due to tension in the direction in which the source region and the drain region are connected is larger than medium and increases the driving capability of the N-type MISFET. Consequently, as the ratio of nickel (Ni) silicide increases, the strain decreases, and the driving capability of the MISFET decreases. However, in the range of the ratio of nickel (Ni) silicide shown by the dotted line 17c, the increase in the driving capability of the MISFET due to the increase in Ezz is large and exceeds the decrease in the driving capability of the MISFET due to the decrease in Exx.

FIG. 3C, which is similar to FIG. 3B, is a graph which shows the relationship between each of Exx (strain in the direction in which the source region and the drain region are connected) and Ezz (strain in the direction vertical to the semiconductor substrate) generated in the channel region and the ratio of nickel (Ni) silicide in the gate electrode 12b in the case where the MISFET of FIG. 3A is an N-type MISFET. FIG. 3C also shows strain for improving the driving capability of the MISFET, the strain being caused through the gate electrode in the channel region of the MISFET under the gate electrode on the basis of the stress generated by the insulating film, and the ratio of silicide in response to the strain in the case where the MISFET of FIG. 3A is an N-type MISFET.

However, FIG. 3C is different in that the range represented by the dotted line 17c is from 0.5 to 0.6. Consequently, in the N-type MISFET of FIG. 3C, the ratio of nickel (Ni) silicide in the gate electrode 12b is limited to a range of 0.5 to 0.6.

In the N-type MISFET of FIG. 3C, when the ratio of nickel (Ni) silicide in the gate electrode 12b is limited to the range of 0.5 to 0.6, since the decrease in Exx (strain in the X direction) does not start, the driving capability of the MISFET further increases largely.

FIG. 3D is a graph which shows the relationship between each of Exx (strain in the direction in which the source region and the drain region are connected) and Ezz (strain in the direction vertical to the semiconductor substrate) generated in the channel region and the ratio of nickel (Ni) silicide in the gate electrode 12b in the case where the MISFET of FIG. 3A is a P-type MISFET. FIG. 3D also shows strain for enhancing the driving capability of the MISFET, the strain being caused through the gate electrode in the channel region of the MISFET under the gate electrode on the basis of the stress generated by the insulating film, and the ratio of silicide in response to the strain in the case where the MISFET of FIG. 3A is a P-type MISFET.

However, FIG. 3D is different in that the range represented by the dotted line 17c is from 0.6 to 1.0. Consequently, in the P-type MISFET of FIG. 3D, the ratio of nickel (Ni) silicide in the gate electrode 12b is limited to a range of 0.6 to 1.0.

Moreover, FIG. 3D is different in that the MISFET of FIG. 3A is a P-type MISFET.

In the P-type MISFET of FIG. 3D, when the ratio of nickel (Ni) silicide in the gate electrode 12b is limited to the range of 0.6 to 1.0, the driving capability of the P-type MISFET improves compared with the case where the gate electrode 12b is composed of polysilicon only.

The reason for the increase in the driving capability of the P-type MISFET will be described below. First, according to the description in the column of PMOS in FIG. 1, in the P-type MISFET, Ezz (strain in the Z direction) hardly causes a change in the current-driving capability. On the other hand, in the P-type MISFET, when Exx (strain in the X direction) is strain due to compression, the driving capability increases largely.

According to the graph of FIG. 3D, at the point where the ratio of nickel (Ni) silicide is 0.6, the decrease in Exx (strain in the X direction), which is a strain due to compression, starts. Therefore, the driving capability of the P-type MISFET increases compared with the case where the gate electrode 12b is composed of polysilicon only. On the other hand, at the point where the ratio of nickel (Ni) silicide is 0.6, the increase in Ezz (strain in the Z direction), which is a strain due to compression, starts. However, in comparison with the case where the gate electrode 12b is composed of polysilicon only, Ezz (strain in the Z direction) hardly contributes to the driving capability of the P-type MISFET.

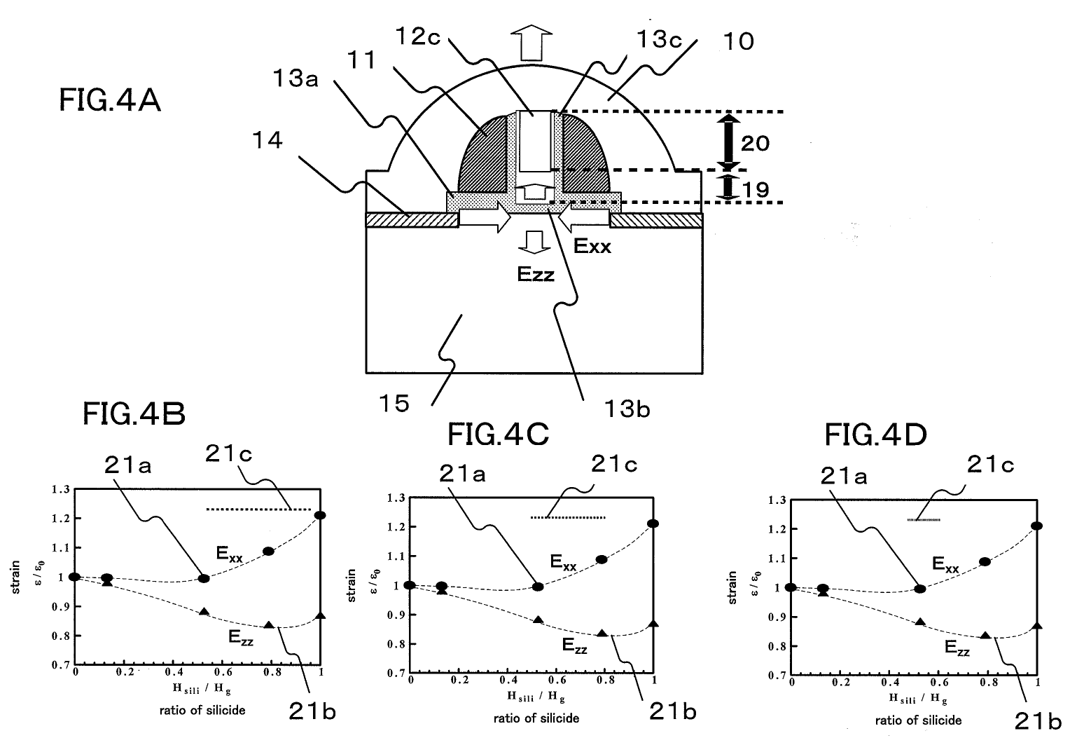

FIGS. 4A to 4D show a cross-sectional view of another MISFET according to Embodiment 1, and graphs showing the strains generated in channel regions of other MISFETs according to Embodiment 1.

FIG. 4A is a cross-sectional view of a MISFET according to Embodiment 1, the MISFET being covered with a contact etching stop film 10 which generates compress stress, the cross-sectional view showing a gate electrode structure which controls Exx (strain in the direction in which a source region and a drain region are connected) and Ezz (strain in the direction vertical to the semiconductor substrate) generated in a channel region.

The another MISFET according to Embodiment 1 is disposed on a principal surface of a semiconductor substrate 15 and covered with a contact etching stop film 10 which causes compress stress in the MISFET. Furthermore, the MISFET shown in FIG. 4A includes a gate insulating film 13b, an oxide film 13a under a sidewall, a gate electrode 12c having a cobalt (Co) silicide portion 20 and a polysilicon portion 19 which are arranged at a predetermined ratio, a sidewall 11 disposed on a side surface of the gate electrode 12c through an oxide film 13c on the sidewall of the gate electrode, and source/drain regions 14 disposed adjacent to both sides of the gate electrode 12c. The same components as those in FIG. 2A are designated by the same reference numerals. However, the gate electrode 12c is different from the gate electrode 12a (composed of polysilicon or silicide) in that the gate electrode 12c has the polysilicon 19 and the cobalt (Co) silicide 20 at a predetermined ratio.

Since the MISFET is compressed from both sides by the contact etching stop film 10 which generates compress stress, tensile stress occurs in the height direction in the gate electrode 12c.

FIG. 4B is a graph which shows the relationship between each of Exx (strain in the direction in which the source region and the drain region are connected) and Ezz (strain in the direction vertical to the semiconductor substrate) generated in the channel region and the ratio of cobalt (Co) silicide in the gate electrode 12c in the case where the MISFET of FIG. 4A is a P-type MISFET. FIG. 4B also shows strain for enhancing the driving capability of the MISFET, the strain being caused through the gate electrode in the channel region of the MISFET under the gate electrode on the basis of the stress generated by the insulating film, and the ratio of silicide in response to the strain in the case where the MISFET of FIG. 4A is an p-type MISFET.

Furthermore, FIG. 4B shows solid circles 21a and a curve connecting the solid circles, solid triangles 21b and a curve connecting the solid triangles 21b, and a dotted line 21c representing a range of the ratio of silicide.

The horizontal axis of the graph of FIG. 4B represents the ratio of the length in the height direction of the silicide portion to the length in the height direction of the entire gate electrode 12c. Furthermore, the vertical axis of the graph of FIG. 4B represents the ratio of the strain in the case where the gate electrode 12c is composed of polysilicon and silicide to the strain in the case where the gate electrode 12c is entirely composed of polysilicon.

The solid circles 21a and the curve connecting the solid circles 21a represent changes in strain relative to the ratio of silicide for the strain (Exx) in the direction in which the source region and the drain region are connected. According to the solid circles 21a and the curve connecting the solid circles 21a, when the ratio of silicide is in a range of 0 to 0.6, the increase in strain does not occur. On the other hand, as the ratio of silicide increases from 0.6 to 1.0, the ratio of strain increases from 1.0 to 1.2.

The reason for this is that, in the case where the gate electrode 12c is composed of cobalt (Co) silicide, Exx (strain in the X direction) increases compared with the case where the gate electrode 12c is composed of polysilicon only as shown in FIG. 2B, and consequently, as the ratio of cobalt (Co) silicide increases in the gate electrode 12c, Exx (strain in the X direction) is considered to increase.

The solid triangles 21b and the curve connecting the solid triangles 21b represent changes in strain relative to the ratio of silicide for the strain (Ezz) in the direction vertical to the semiconductor substrate. According to the solid triangles 21b and the curve connecting the solid triangles 21b, as the ratio of silicide increases from 0 to 0.60, the ratio of strain decreases from 1.0 to 0.85. Even if the ratio of silicide increases from 0.60 to 1.0, the ratio of strain is maintained. The reason for this is that, in the case where the gate electrode 12c is composed of cobalt (Co) silicide, Ezz (strain in the Z direction) decreases compared with the case where the gate electrode 12c is composed of polysilicon only as shown in FIG. 2B, and consequently, as the ratio of cobalt (Co) silicide increases in the gate electrode 12c, Ezz (strain in the Z direction) is considered to decrease.

The dotted line 21c representing a range of the ratio of silicide shows the range of the ratio of silicide in response to the strain which increases the current-driving capability of the P-type MISFET of FIG. 4B, i.e., a range of 0.6 to 1.0.

That is, in the P-type MISFET of FIG. 4B, the ratio of cobalt (Co) silicide in the gate electrode 12c is limited to a range of 0.6 to 1.0.

The reason for the increase in the current-driving capability of the P-type MISFET of FIG. 4B will be described below. First, according to the table of FIG. 1, in the channel region of the P-type MISFET, the strain due to compression in the direction in which the source region and the drain region are connected largely increases the driving capability of the P-type MISFET. Consequently, as the ratio of cobalt (Co) silicide increases, the strain increases, and the driving capability of the MISFET increases. On the other hand, in the channel region of the P-type MISFET, the strain in the direction vertical to the semiconductor substrate does not affect the driving capability of the P-type MISFET. Consequently, in the range of the ratio of cobalt (Co) silicide represented by the dotted line 21c, the increase in the driving capability of the MISFET due to the increase in Exx becomes large.

FIG. 4C is a graph which shows the relationship between each of Exx (strain in the direction in which the source region and the drain region are connected) and Ezz (strain in the direction vertical to the semiconductor substrate) generated in the channel region and the ratio of cobalt (Co) silicide in the gate electrode 12c in the case where the MISFET of FIG. 4A is an N-type MISFET. FIG. 4C is a graph which also shows strain for enhancing the driving capability of the MISFET, the strain being caused through the gate electrode in the channel region of the MISFET under the gate electrode on the basis of the stress generated by the insulating film, and the ratio of silicide in response to the strain in the case where the MISFET of FIG. 4A is an N-type MISFET.

However, FIG. 4C is different in that the range represented by the dotted line 21c is 0.5 to 0.8. Consequently, in the N-type MISFET of FIG. 4C, the ratio of cobalt (Co) silicide in the gate electrode 12c is limited to a range of 0.5 to 0.8.

In the N-type MISFET of FIG. 4C, when the ratio of cobalt (Co) silicide in the gate electrode 12c is limited to the range of 0.5 to 0.9, the increase in Exx (strain in the X direction) just starts. On the other hand, Ezz (strain in the Z direction) largely decreases. In consideration of the table of FIG. 1, as Exx (strain in the X direction) in the compression direction increases, the driving capability of the N-type MISFET tends to decrease. On the other hand, as Ezz (strain in the Z direction) in the tension direction decreases, the driving capability of the N-type MISFET tends to increase. In this case, since the decrease in Ezz (strain in the Z direction) more largely contributes to the increase in the driving capability, and since the degree of decrease in Ezz (strain in the Z direction) is large, the driving capability of the N-type MISFET of FIG. 4C increases.

FIG. 4D is a graph which shows the relationship between each of Exx (strain in the direction in which the source region and the drain region are connected) and Ezz (strain in the direction vertical to the semiconductor substrate) generated in the channel region and the ratio of cobalt (Co) silicide in the gate electrode 12c in the case where the MISFET of FIG. 4A is an N-type MISFET. FIG. 4D is a graph which also shows strain for enhancing the driving capability of the MISFET, the strain being caused through the gate electrode in the channel region of the MISFET under the gate electrode on the basis of the stress generated by the insulating film, and the ratio of silicide in response to the strain in the case where the MISFET of FIG. 4A is an N-type MISFET.

However, FIG. 4D is different in that the range represented by the dotted line 21c is 0.5 to 0.6. Consequently, in the N-type MISFET of FIG. 4D, the ratio of cobalt (Co) silicide in the gate electrode 12c is limited to a range of 0.5 to 0.6.

In the N-type MISFET of FIG. 4D, when the ratio of cobalt (Co) silicide in the gate electrode 12c is limited to the range of 0.5 to 0.6, the driving capability of the N-type MISFET improves compared with the case where the gate electrode 12c is composed of polysilicon only. The reason for this is the same as the reason for the improvement in the driving capability of the N-type MISFET of FIG. 4C. Consequently, when the ratio of cobalt (Co) silicide is limited to the range of 0.5 to 0.6, the reason for the improvement in the driving capability of the N-type MISFET of FIG. 4C is further enhanced, and thus the driving capability of the N-type MISFET of FIG. 4D improves.

The descriptions on FIGS. 3A to 3D and FIGS. 4A to 4D lead to the following findings.

First, in the N-type MISFET of FIG. 3B, the ratio of nickel (Ni) silicide in the gate electrode 12b is limited to the range of 0.5 to 1.0. Consequently, as the ratio of nickel (Ni) silicide in the gate electrode increases in the channel region of the N-type MISFET of FIG. 3B, the strain due to compressive force in the direction vertical to the semiconductor substrate (Ezz: strain in the Z direction) increases, and the driving capability of the N-type MISFET of FIG. 3B increases.

In the N-type MISFET of FIG. 3C, the ratio of nickel (Ni) silicide in the gate electrode 12b is limited to the range of 0.5 to 0.6. In the N-type MISFET of FIG. 3C, when the ratio of nickel (Ni) silicide in the gate electrode 12b is limited to the range of 0.5 to 0.6, since the decrease in the strain in the direction in which the source region and the drain region are connected (Exx: strain in the X direction) does not start, the driving capability of the MISFET further increases largely.

In the P-type MISFET of FIG. 3D, the ratio of nickel (Ni) silicide in the gate electrode 12b is limited to the range of 0.6 to 1.0. As a result, Exx due to compression (strain in the X direction) decreases. Consequently, the driving capability of the P-type MISFET increases compared with the case where the gate electrode 12b is composed of polysilicon only.

Furthermore, although nickel (Ni) silicide is used in FIGS. 3B to 3D, the same effect will be produced if the Young's modulus is larger than that of polysilicon. Consequently, even when titanium (Ti) silicide is used as the silicide, the same effect as that of nickel (Ni) silicide is produced.

In the P-type MISFET of FIG. 4B, the ratio of cobalt (Co) silicide in the gate electrode 12c is limited to the range of 0.6 to 1.0. The reason for the increase in the driving capability of the P-type MISFET of FIG. 4B will be described below. First, in the channel region of the P-type MISFET, the strain due to compression in the direction in which the source region and the drain region are connected largely increases the driving capability of the P-type MISFET.

In the N-type MISFET of FIG. 4C, the ratio of cobalt (Co) silicide in the gate electrode 12c is limited to the range of 0.5 to 0.9. In the N-type MISFET of FIG. 4C, when the ratio of cobalt (Co) silicide in the gate electrode 12c is limited to the range of 0.5 to 0.9, Ezz (strain in the Z direction) largely decreases. Consequently, the driving capability of the N-type MISFET of FIG. 4C increases due to the decrease in Ezz (strain in the Z direction) in the tension direction.

In the N-type MISFET of FIG. 4D, the ratio of cobalt (Co) silicide in the gate electrode 12c is limited to the range of 0.5 to 0.6. When the ratio of cobalt (Co) silicide in the gate electrode 12c is limited to the range of 0.5 to 0.6, the increase in Exx (strain in the X direction) just starts. On the other hand, Ezz (strain in the Z direction) largely decreases. Consequently, the driving capability of the N-type MISFET of FIG. 4D tends to increase.

Furthermore, although cobalt (Co) silicide is used in FIGS. 4B to 4D, the same effect will be of course produced if the Young's modulus is smaller than that of polysilicon.

That is, in each of the P-type MISFET and the N-type MISFET covered with a contact etching stop film having tensile stress, when the gate electrode is composed of a polysilicon portion and a nickel (Ni) silicide portion, by limiting the ratio between the polysilicon portion and the nickel (Ni) silicide portion, a predetermined strain can be caused in the channel region of the MISFET, and the driving capability of the MISFET can be improved. Note that, in the tensile stress film, since a tensile stress occurs in the film itself, a force that presses the MISFET toward the semiconductor substrate is generated.

Similarly, in each of the P-type MISFET and the N-type MISFET covered with a contact etching stop film having compress stress, when the gate electrode is composed of a polysilicon portion and a cobalt (Co) silicide portion, by limiting the ratio between the polysilicon portion and the cobalt (Co) silicide portion, a predetermined strain can be caused in the channel region of the MISFET, and the driving capability of the MISFET can be improved. Note that, in the compress stress film, since a compressive stress occurs in the film itself, a force that pulls the MISFET from the semiconductor substrate is generated.

### Embodiment 2

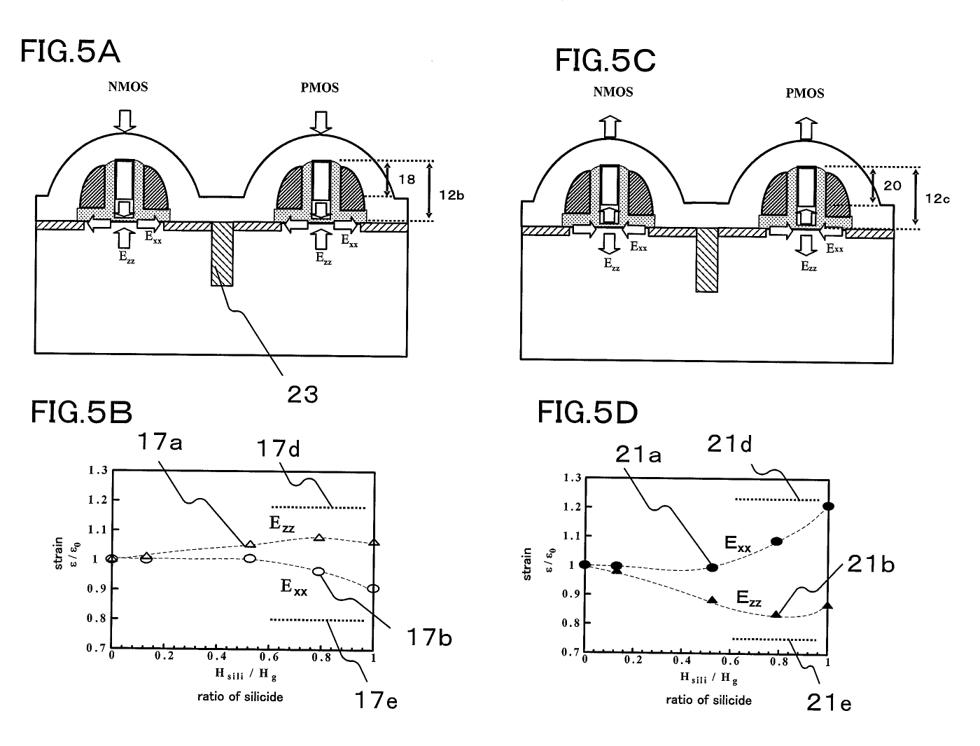

Embodiment 2 relates to a semiconductor device in which an N-type MISFET and a P-type MISFET are together disposed on a principal surface of a semiconductor substrate. Embodiment 2 will be described with reference to FIGS. 5A, 5B, 5C, and 5D.

FIGS. 5A to 5D show cross-sectional views of semiconductor devices according to Embodiment 2, and graphs showing the ratio between the polysilicon portion and the silicide portion constituting the gate electrode of each of the N-type MISFET and the P-type MISFET. Furthermore, FIGS. 5A to 5D show a contact etching stop film 10, a sidewall 11, a gate electrode 12b, a gate electrode 12c, an oxide film 13a under the sidewall 11, a gate insulating film 13b, an oxide film 13c on the sidewall of the gate electrode, source/drain regions 14, a semiconductor substrate 15, open triangles 17a and a curve connecting the open triangles 17a, open circles 17b and a curve connecting the open circles 17b, a dotted line 17d representing a range of the ratio of silicide in the gate electrode of the N-type MISFET, a dotted line 17e representing a range of the ratio of silicide in the gate electrode of the P-type MISFET, a nickel (Ni) silicide portion 18, a polysilicon portion 19, a cobalt (Co) silicide portion 20, solid circles 21a and a curve connecting the solid circles 21a, solid triangles 21b and a curve connecting the solid triangles 21b, a dotted line 21d representing a range of the ratio of silicide in the gate electrode of the N-type MISFET, a dotted line 21e representing a range of the ratio of silicide in the gate electrode of the P-type MISFET, and an element isolation portion 23.

FIG. 5A is a cross-sectional view of a semiconductor device in which the N-type MISFET of FIG. 3B and the P-type MISFET of FIG. 3D are disposed on a principal surface of a semiconductor substrate 15, the N-type MISFET and the P-type MISFET being covered with a contact etching stop film 10 which generates tensile stress.

The N-type MISFET of FIG. 3B has a structure including the sidewall 11, the gate electrode 12b, the oxide film 13a under the sidewall 11, the gate insulating film 13b, the oxide film 13c on the sidewall of the gate electrode, and the source/drain regions 14. Note that the impurity implanted into the source/drain regions 14 is of N type. Furthermore, the P-type MISFET of FIG. 3D has the same structure as the above except that the impurity implanted into the source/drain regions 14 is of P type.

Furthermore, the N-type MISFET and the P-type MISFET are electrically isolated from each other by the element isolation portion 23.

The gate electrode 12b includes the nickel (Ni) silicide portion 18 and the polysilicon portion 19.

FIG. 5B, which is similar to FIG. 3B, is a graph which shows the ratio between the nickel (Ni) silicide portion 18 and the polysilicon portion 19 in the gate electrodes 12b of the MISFETs constituting the semiconductor device of FIG. 5A.

According to the dotted line 17d representing the range of the ratio of silicide in the gate electrode of the N-type MISFET and the dotted line 17e representing the range of the ratio of silicide in the gate electrode of the P-type MISFET, which are shown in FIG. 5B, in the gate electrode 12b of the N-type MISFET and the gate electrode 12b of the P-type MISFET, the ratio between the nickel (Ni) silicide portion 18 and the polysilicon portion 19 is in a range of 0.6 to 0.9.

When the ratio between the nickel (Ni) silicide portion 18 and the polysilicon portion 19 is in the range of 0.6 to 0.9, in the semiconductor device of FIG. 5A, the current-driving capability improves in both the N-type MISFET and the P-type MISFET. The reason for this is that the same effect is produced as in the case where, in the N-type MISFET of FIG. 3B and the P-type MISFET of FIG. 3D, the ratio between the nickel (Ni) silicide portion 18 and the polysilicon portion 19 is limited to the range of 0.6 to 0.9.

FIG. 5C is a cross-sectional view of a semiconductor device in which the N-type MISFET of FIG. 4C and the P-type MISFET of FIG. 4B are disposed on a principal surface of a semiconductor substrate 15, the N-type MISFET and the P-type MISFET being covered with a contact etching stop film 10 which generates compressive stress.

The N-type MISFET of FIG. 4C has a structure including the sidewall 11, the gate electrode 12c, the oxide film 13a under the sidewall 11, the gate insulating film 13b, the oxide film 13c on the sidewall of the gate electrode, and the source/drain regions 14. Note that the impurity implanted into the source/drain regions 14 is of N type. Furthermore, the P-type MISFET of FIG. 4B has the same structure as the above except that the impurity implanted into the source/drain regions 14 is of P type.

Furthermore, the N-type MISFET and the P-type MISFET are electrically isolated from each other by the element isolation portion 23.

The gate electrode 12c includes the cobalt (Co) silicide portion 20 and the polysilicon portion 19.

FIG. 5D, which is similar to FIG. 4B, is a graph which shows the ratio between the cobalt (Co) silicide portion 20 and the polysilicon portion 19 in the gate electrodes 12c of the MISFETs constituting the semiconductor device of FIG. 5C.

According to the dotted line 21d representing the range of the ratio of silicide in the gate electrode of the N-type MISFET and the dotted line 21e representing the range of the ratio of silicide in the gate electrode of the P-type MISFET, which are shown in FIG. 5C, in the gate electrode 12c of the N-type MISFET and the gate electrode 12c of the P-type MISFET, the ratio between the cobalt (Co) silicide portion 20 and the polysilicon portion 19 is in a range of 0.6 to 0.9.

When the ratio between the cobalt (Co) silicide portion 20 and the polysilicon portion 19 is in the range of 0.6 to 0.9, in the semiconductor device of FIG. 5C, the current-driving capability improves in both the N-type MISFET and the P-type MISFET. The reason for this is that the same effect is produced as in the case where, in the N-type MISFET of FIG. 4C and the P-type MISFET of FIG. 4B, the ratio between the cobalt (Co) silicide portion 20 and the polysilicon portion 19 is limited to the range of 0.6 to 0.9.

### Embodiment 3

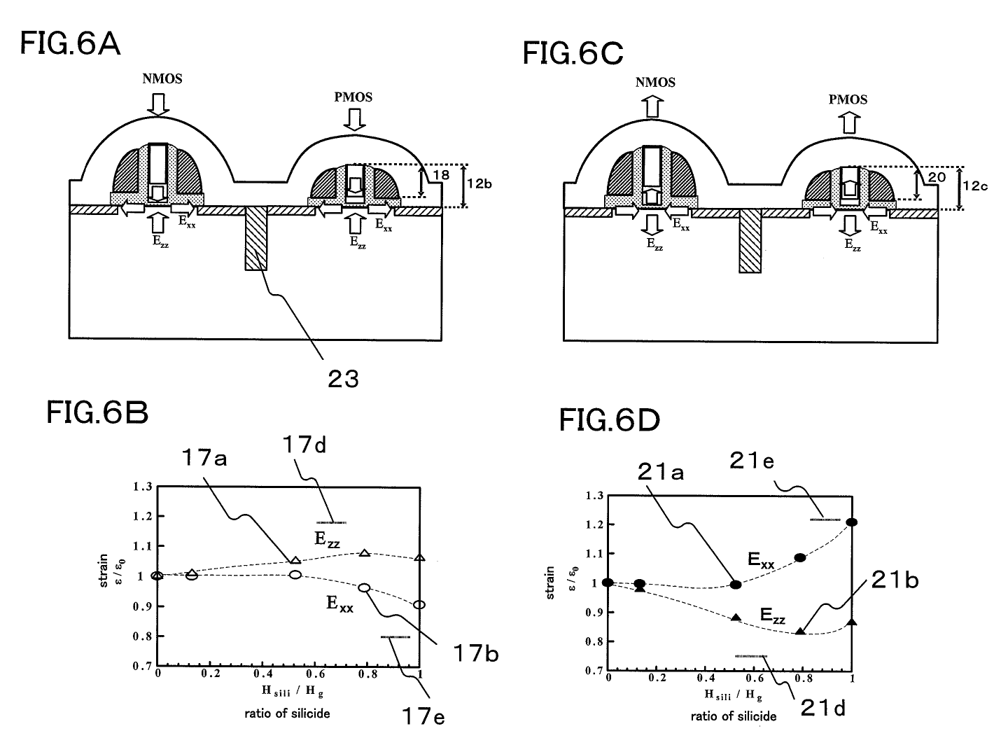

Embodiment 3 relates to a semiconductor device in which an N-type MISFET and a P-type MISFET are together disposed on a principal surface of a semiconductor substrate. However, the ratio between the silicide and polysilicon constituting the gate electrode of the N-type MISFET is different from the ratio between the silicide and polysilicon constituting the gate electrode of the P-type MISFET. Embodiment 3 will be described with reference to FIGS. 6A, 6B, 6C, and 6D.

FIGS. 6A to 6D show cross-sectional views of semiconductor devices according to Embodiment 3, and graphs showing the ratio between the polysilicon portion and the silicide portion constituting the gate electrode of each of the N-type MISFET and the P-type MISFET. Furthermore, FIGS. 6A to 6D show a contact etching stop film 10, a sidewall 11, a gate electrode 12b, a gate electrode 12c, an oxide film 13a under the sidewall 11, a gate insulating film 13b, an oxide film 13c on the sidewall of the gate electrode, source/drain regions 14, a semiconductor substrate 15, open triangles 17a and a curve connecting the open triangles 17a, open circles 17b and a curve connecting the open circles 17b, a dotted line 17d representing a range of the ratio of silicide in the gate electrode of the N-type MISFET, a dotted line 17e representing a range of the ratio of silicide in the gate electrode of the P-type MISFET, a nickel (Ni) silicide portion 18, a polysilicon portion 19, a cobalt (Co) silicide portion 20, solid circles 21a and a curve connecting the solid circles 21a, solid triangles 21b and a curve connecting the solid triangles 21b, a dotted line 21d representing a range of the ratio of silicide in the gate electrode of the N-type MISFET, a dotted line 21e representing a range of the ratio of silicide in the gate electrode of the P-type MISFET, and an element isolation portion 23.

FIG. 6A is a cross-sectional view of a semiconductor device in which the N-type MISFET of FIG. 3C and the P-type MISFET of FIG. 3D are disposed on a principal surface of a semiconductor substrate 15, the N-type MISFET and the P-type MISFET being covered with a contact etching stop film 10 which generates tensile stress.

The N-type MISFET of FIG. 3C has a structure including the sidewall 11, the gate electrode 12b, the oxide film 13a under the sidewall 11, the gate insulating film 13b, the oxide film 13c on the sidewall of the gate electrode, and the source/drain regions 14. Note that the impurity implanted into the source/drain regions 14 is of N type. Furthermore, the P-type MISFET of FIG. 3D has the same structure as the above except that the impurity implanted into the source/drain regions 14 is of P type.

The gate electrode 12b includes a nickel (Ni) silicide portion 18 and a polysilicon portion 19. Furthermore, the ratio between the nickel (Ni) silicide portion 18 and the polysilicon portion 19 in the gate electrode 12b of the N-type MISFET of FIG. 3C is different from the ratio between the nickel (Ni) silicide portion 18 and the polysilicon portion 19 in the gate electrode 12b of the P-type MISFET of FIG. 3D. The reason for this is that, although the length of the nickel (Ni) silicide portion 18 in the N-type MISFET of FIG. 3C is the same as the length of the nickel (Ni) silicide portion 18 in the P-type MISFET of FIG. 3D, the length of the gate electrode 12b of the P-type MISFET is longer, and thus the ratio between the nickel (Ni) silicide portion 18 and the polysilicon portion 19 varies.

Furthermore, the N-type MISFET and the P-type MISFET are electrically isolated from each other by the element isolation portion 23.

FIG. 6B, which is similar to FIG. 3C, is a graph which shows the ratio between the nickel (Ni) silicide portion 18 and the polysilicon portion 19 in the gate electrodes 12b of the MISFETs constituting the semiconductor device of FIG. 6A.

According to the dotted line 17d representing the range of the ratio of silicide in the gate electrode of the N-type MISFET and the dotted line 17e representing the range of the ratio of silicide in the gate electrode of the P-type MISFET, in the gate electrode 12b of the N-type MISFET, which are shown in FIG. 6B, the ratio between the nickel (Ni) silicide portion 18 and the polysilicon portion 19 is in a range of 0.5 to 0.6. On the other hand, in the gate electrode 12b of the P-type MISFET, the ratio between the nickel (Ni) silicide portion 18 and the polysilicon portion 19 is in a range of 0.8 to 0.9.

When the ratio between the nickel (Ni) silicide portion 18 and the polysilicon portion 19 in the P-type MISFET and the N-type MISFET is in the ranges described above, in the semiconductor device of FIG. 6A, the current-driving capability improves in both the N-type MISFET and the P-type MISFET. The reason for this is that the same effect is produced as in the case where, in the N-type MISFET of FIG. 3C, the ratio between the nickel (Ni) silicide portion 18 and the polysilicon portion 19 is limited to the range of 0.5 to 0.6, and that the same effect is produced as in the case where, in the P-type MISFET of FIG. 3D, the ratio between the nickel (Ni) silicide portion 18 and the polysilicon portion 19 is limited to the range of 0.8 to 0.9.

FIG. 6C is a cross-sectional view of a semiconductor device in which the N-type MISFET of FIG. 4D and the P-type MISFET of FIG. 4B are disposed on a principal surface of a semiconductor substrate 15, the N-type MISFET and the P-type MISFET being covered with a contact etching stop film 10 which generates compressive stress.

The N-type MISFET of FIG. 4D has a structure including the sidewall 11, the gate electrode 12c, the oxide film 13a under the sidewall 11, the gate insulating film 13b, the oxide film 13c on the sidewall of the gate electrode, and the source/drain regions 14. Note that the impurity implanted into the source/drain regions 14 is of N type. Furthermore, the P-type MISFET of FIG. 4B has the same structure as the above except that the impurity implanted into the source/drain regions 14 is of P type.

Furthermore, the N-type MISFET and the P-type MISFET are electrically isolated from each other by the element isolation portion 23.

The gate electrode 12c includes the cobalt (Co) silicide portion 20 and the polysilicon portion 19. Furthermore, the ratio between the cobalt (Co) silicide portion 20 and the polysilicon portion 19 in the gate electrode 12c of the N-type MISFET of FIG. 4D is different from the ratio between the cobalt (Co) silicide portion 20 and the polysilicon portion 19 in the gate electrode 12c of the P-type MISFET of FIG. 4B. The reason for this is that, although the length of the cobalt (Co) silicide portion 20 in the N-type MISFET of FIG. 4D is the same as the length of the cobalt (Co) silicide portion 20 in the P-type MISFET of FIG. 4B, the length of the gate electrode 12c of the N-type MISFET is longer, and thus the ratio between the cobalt (Co) silicide portion 20 and the polysilicon portion 19 varies.

FIG. 6D, which is similar to FIG. 4B, is a graph which shows the ratio between the cobalt (Co) silicide portion 20 and the polysilicon portion 19 in the gate electrodes 12c of the MISFETs constituting the semiconductor device of FIG. 6C.

According to the dotted line 21d representing the range of the ratio of silicide in the gate electrode of the N-type MISFET and the dotted line 21e representing the range of the ratio of silicide in the gate electrode of the P-type MISFET, which are shown in FIG. 6C, in the gate electrode 12c of the N-type MISFET, the ratio between the cobalt (Co) silicide portion 20 and the polysilicon portion 19 is in a range of 0.5 to 0.6. On the other hand, in the gate electrode 12c of the P-type MISFET, the ratio between the cobalt (Co) silicide portion 20 and the polysilicon portion 19 is in a range of 0.8 to 0.9.

When the ratio between the cobalt (Co) silicide portion 20 and the polysilicon portion 19 is in the ranges described above in the N-type MISFET and the P-type MISFET, in the semiconductor device of FIG. 6C, the current-driving capability improves in both the N-type MISFET and the P-type MISFET. The reason for this is that the same effect is produced as in the case where, in the N-type MISFET of FIG. 4D, the ratio between the cobalt (Co) silicide portion 20 and the polysilicon portion 19 is limited to the range of 0.5 to 0.6, and that the same effect is produced as in the case where, in the P-type MISFET of FIG. 4B, the ratio between the cobalt (Co) silicide portion 20 and the polysilicon portion 19 is limited to the range of 0.8 to 0.9.

### Embodiment 4

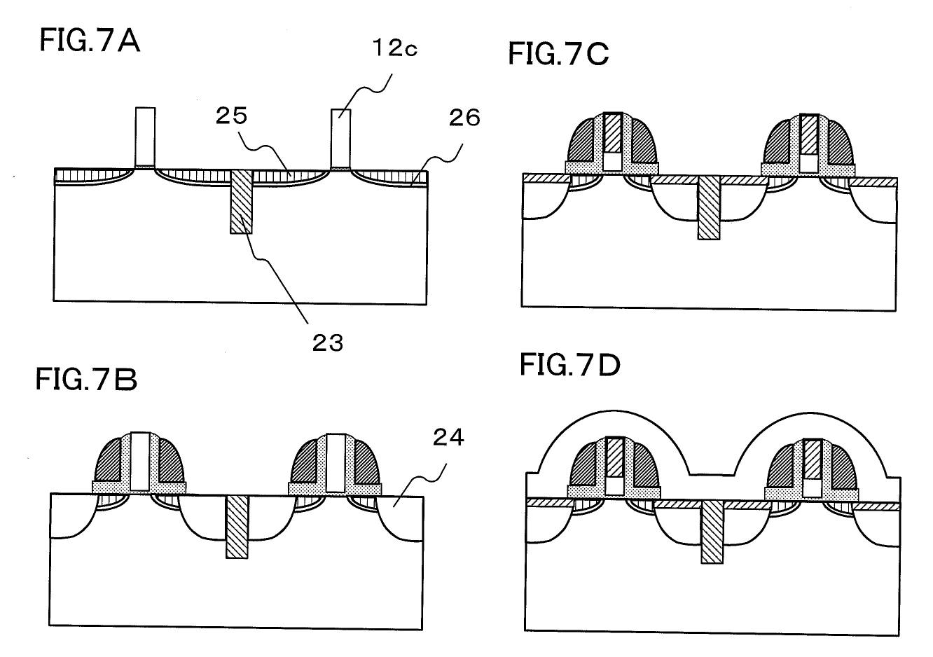

Embodiment 4 relates to a method for manufacturing the semiconductor device shown in FIG. 5A or 5C. In the semiconductor device, the ratio between the polysilicon and the silicide constituting the gate electrode of the P-type MISFET is the same as the ratio between the polysilicon and the silicide constituting the gate electrode of the N-type MISFET. Embodiment 4 will be described with reference to FIGS. 7A to 7D.

FIGS. 7A to 7D are cross-sectional views showing the steps in a method for manufacturing the semiconductor device shown in FIG. 5A or 5C. Furthermore, FIGS. 7A to 7D show a contact etching stop film 10, a sidewall 11, a gate electrode 12d, an oxide film 13a under the sidewall 11, a gate insulating film 13b, an oxide film 13c on the sidewall of the gate electrode, source/drain regions 14, a semiconductor substrate 15, a nickel (Ni) silicide portion 18, a polysilicon portion 19, a cobalt (Co) silicide portion 20, an element isolation portion 23, deep impurity diffusion regions 24 constituting the source/drain regions 14, shallow impurity diffusion regions constituting the source/drain regions 14, i.e., extension regions 25, and punch-through stop impurity regions 26.

FIG. 7A is a cross-sectional view showing a state in which the gate electrodes 12c are formed. In order to obtain the cross-sectional view shown in FIG. 7A, the following step is carried out.

First, a groove for the element isolation portion 23 is formed on the semiconductor substrate 15 by etching using, as a mask, a resist pattern formed by photolithography. An insulating material is deposited so that the groove is filled with the insulating material, and then the insulating material in a region other than the groove is removed by a CMP (chemical mechanical polishing) method. Thereby, the element isolation portion 23 is formed.

Then, as the gate insulating film 13b, for example, silicon oxynitride (SiON) is deposited, and a polysilicon layer is deposited on the gate insulating film 13b. A resist is applied onto the polysilicon layer, and a resist pattern corresponding to the gate electrodes 12d is formed by photolithography. Anisotropic etching is performed on the polysilicon layer using the resist pattern as a mask. Thereby, a polysilicon pattern corresponding to a gate electrode pattern is formed. Then, an impurity is implanted into the extension regions 25 and the punch-through stop impurity regions 26 by an ion implantation method. As a result, the cross-sectional view shown in FIG. 7A is obtained.

FIG. 7B is a cross-sectional view showing a state in which the side walls 11 are formed on the side surfaces of the polysilicon pattern for the gate electrodes 12d, and an impurity is implanted into the deep impurity diffusion regions 24 constituting the source/drain regions 14. In order to obtain the cross-sectional view shown in FIG. 7B, the following step is carried out.

First, an oxide film is deposited, and a nitride film is further deposited on the oxide film. By performing anisotropic etching on the nitride film, sidewalls 11 composed of the nitride are formed on the sidewalls of the polysilicon pattern through the oxide film 13c. Then, using the sidewalls 11 as masks, the oxide film is etched to form oxide films 13a under the sidewalls 11 and to remove the oxide on the polysilicon pattern. Then, by implanting an impurity into the deep impurity diffusion regions 24 constituting the source/drain regions 14, the cross-sectional view of FIG. 7B is obtained.

FIG. 7C is a cross-sectional view showing a state in which silicide is disposed on the source/drain regions and the polysilicon pattern. In order to obtain the cross-sectional view shown in FIG. 7C, the following step is carried out. First, in order to activate the impurity, heat treatment is performed so that the impurity in each of the deep impurity diffusion regions 24 and the extension regions 25 constituting the source/drain regions 14, and the punch-through stop impurity regions 26 is activated. Then, by a sputtering method or a CVD (chemical vapor deposition) method, a layer of a metal constituting the silicide, for example, a layer of a metal, such as nickel (Ni), titanium (Ti), or cobalt (Co), is formed. Then, by performing heat treatment for forming the silicide, the gate electrodes 12d composed of polysilicon and silicide are formed. In this step, the heat treatment for forming the silicide plays an important role in determining the ratio between the polysilicon portion 19 and the nickel (Ni) silicide portion 18, cobalt (Co) silicide portion 20, or the like. For example, by performing heat treatment at 700° C. for about 60 seconds, the ratio between the polysilicon portion 19 and the cobalt (Co) silicide portion 20 can be set to be 50:50. Furthermore, by performing heat treatment at 400° C. for about 60 seconds, the ratio between the polysilicon portion 19 and the nickel (Ni) silicide portion 18 can be set to be 50:50.

FIG. 7D is a cross-sectional view showing a state in which the contact etching stop film 10 is formed. The contact etching stop film 10 can be deposited by a plasma CVD method or the like. In this step, a contact etching stop film 10 which generates tensile stress is formed by depositing a silicon nitride (SiN) film by a plasma CVD method using silicon hydride (SiH4) gas and ammonia (NH4) gas, and then by separating hydrogen in the UV cure step. On the other hand, a contact etching stop film 10 which generates compressive stress is formed by depositing a silicon nitride (SiN) film in which carbon is mixed by a plasma CVD method using silicon hydride (SiH4) gas, ammonia (NH4) gas, and carbon-containing gas.

According to the manufacturing method of FIGS. 7A to 7D, the height of the gate electrode 12d is determined by the thickness of the polysilicon layer for forming the gate electrode and the increase in volume when the silicide is formed by reaction of polysilicon with the metal. Furthermore, the ratio between the polysilicon and the silicide constituting the gate electrode 12d can be controlled by the heat treatment time and the heat treatment temperature during the formation of the silicide. Furthermore, the P-type MISFET and the N-type MISFET have substantially the same ratio between the polysilicon and the silicide constituting the gate electrode 12d.

Consequently, when the contact etching stop film 10 generates tensile stress, the ratio between the polysilicon and the silicide constituting the gate electrode 12d can be set as shown in FIG. 5B. Furthermore, when the contact etching stop film 10 generates compressive stress, the ratio between the polysilicon and the silicide constituting the gate electrode 12d can be set as shown in FIG. 5D.

As a result, it is possible to generate strain that increases the driving capability of the MISFETs in the semiconductor device manufactured by the manufacturing method of Embodiment 4.

Consequently, in the semiconductor device manufactured by the manufacturing method of Embodiment 4, current driving is increased in both the P-type MISFET and the N-type MISFET.

### Embodiment 5

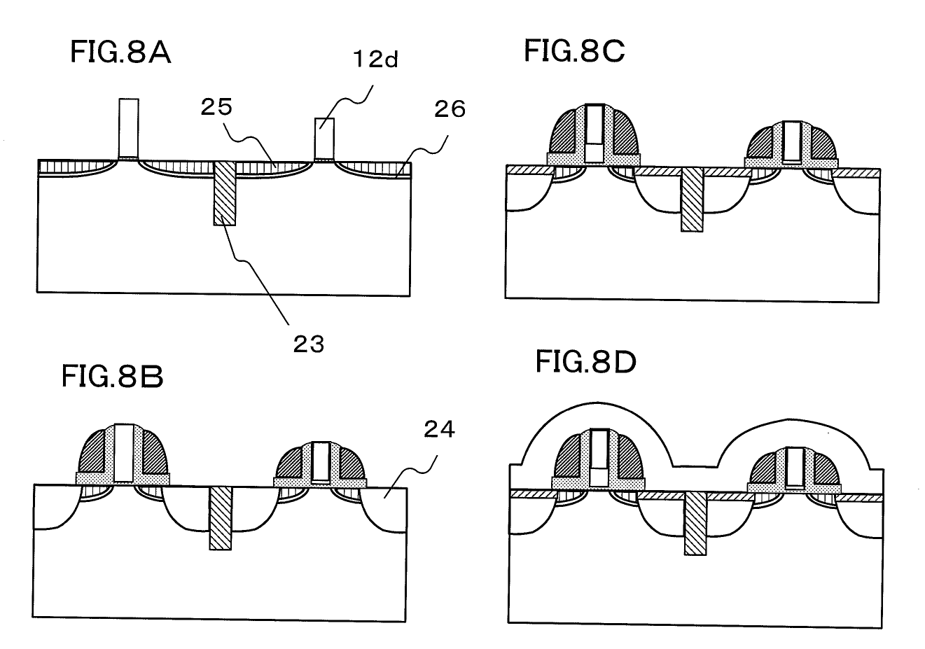

Embodiment 5 relates to a method for manufacturing the semiconductor device shown in FIG. 6A or 6C. In the semiconductor device, the ratio between the polysilicon and the silicide constituting the gate electrode of the P-type MISFET is different from the ratio between the polysilicon and the silicide constituting the gate electrode of the N-type MISFET. Embodiment 5 will be described with reference to FIGS. 8A to 8D.

FIGS. 8A to 8D are cross-sectional views showing the steps in a method for manufacturing the semiconductor device shown in FIG. 6A or 6C. Furthermore, FIGS. 8A to 8D show a contact etching stop film 10, a sidewall 11, a gate electrode 12d, an oxide film 13a under the sidewall 11, a gate insulating film 13b, an oxide film 13c on the sidewall of the gate electrode, source/drain regions 14, a semiconductor substrate 15, a nickel (Ni) silicide portion 18, a polysilicon portion 19, a cobalt (Co) silicide portion 20, an element isolation portion 23, deep impurity diffusion regions 24 constituting the source/drain regions 14, shallow impurity diffusion regions constituting the source/drain regions 14, i.e., extension regions 25, and punch-through stop impurity regions 26.

FIG. 8A is a cross-sectional view showing a state in which the gate electrodes 12d are formed. In order to obtain the cross-sectional view shown in FIG. 8A, the following step is carried out.

First, a groove for the element isolation portion 23 is formed on the semiconductor substrate 15 by etching using, as a mask, a resist pattern formed by photolithography. An insulating material is deposited so that the groove is filled with the insulating material, and then the insulating material in a region other than the groove is removed by a CMP method. Thereby, the element isolation portion 23 is formed.

Then, as the gate insulating film 13b, for example, silicon oxynitride (SiON) is deposited, and a polysilicon layer is deposited on the gate insulating film 13b. A resist is applied onto the polysilicon layer, and a resist pattern corresponding to the gate electrodes 12d is formed by photolithography. Anisotropic etching is performed on the polysilicon layer using the resist pattern as a mask. Thereby, a polysilicon pattern corresponding to a gate electrode pattern is formed.

Then, a resist is applied onto the entire surface, and a resist pattern that covers the gate electrode 12d of the N-type MISFET is formed by photolithography. Next, the gate electrode 12d of the P-type MISFET is formed by etching a predetermined amount by anisotropic etching. Then, the resist pattern is removed. As a result, the length of the gate electrode 12d of the P-type MISFET is smaller than the length of the gate electrode 12d of the N-type MISFET.

Then, an impurity is implanted into the extension regions 25 and the punch-through stop impurity regions 26 by an ion implantation method. As a result, the cross-sectional view shown in FIG. 8A is obtained.

FIG. 8B is a cross-sectional view showing a state in which the side walls 11 are formed on the side surfaces of the polysilicon pattern for the gate electrodes 12d, and an impurity is implanted into the deep impurity diffusion regions 24 constituting the source/drain regions 14. In order to obtain the cross-sectional view shown in FIG. 8B, the same step as in FIG. 7B is carried out.

FIG. 8C is a cross-sectional view showing a state in which silicide is disposed on the source/drain regions and the polysilicon pattern. In order to obtain the cross-sectional view shown in FIG. 8C, the same step as in FIG. 7C is carried out. However, since the length of the gate electrode 12d of the N-type MISFET is different from the length of the gate electrode 12d of the P-type MISFET, the ratio between the polysilicon and the silicide in the gate electrode 12d differs between the two MISFETs.

FIG. 8D is a cross-sectional view showing a state in which the contact etching stop film 10 is formed. The contact etching stop film 10 can be deposited by a plasma CVD method or the like. In this step, a contact etching stop film 10 which generates tensile stress is formed by depositing a silicon nitride (SiN) film by a plasma CVD method using silicon hydride (SiH4) gas and ammonia (NH4) gas, and then by separating hydrogen in the UV cure step. On the other hand, a contact etching stop film 10 which generates compressive stress is formed by depositing a silicon nitride (SiN) film in which carbon is mixed by a plasma CVD method using silicon hydride (SiH4) gas, ammonia (NH4) gas, and carbon-containing gas.

According to the manufacturing method of FIGS. 8A to 8D, the height of the gate electrode 12d is determined by the thickness of the polysilicon layer for forming the gate electrode, the amount of subsequent etching of the polysilicon pattern, and the increase in volume when the silicide is formed by reaction of polysilicon with the metal. Furthermore, the ratio between the polysilicon and the silicide constituting the gate electrode 12d can be controlled by the heat treatment time and the heat treatment temperature during the formation of the silicide. In this case, since the polysilicon pattern for the gate electrode 12d of the N-type MISFET is not etched, the gate electrode 12d has a large height. On the other hand, the length of the silicide portion is substantially the same between the gate electrode 12d of the P-type MISFET and the gate electrode 12d of the N-type MISFET. Consequently, the ratio between the polysilicon and the silicide constituting the gate electrode 12d of the P-type MISFET is different from that of the N-type MISFET.

Consequently, when the contact etching stop film 10 generates tensile stress, the ratio between the polysilicon and the silicide constituting the gate electrode 12d can be set as shown in FIG. 6B. Furthermore, when the contact etching stop film 10 generates compressive stress, the ratio between the polysilicon and the silicide constituting the gate electrode 12d can be set as shown in FIG. 6D.

As a result, it is possible to generate strain that increases the driving capability of the MISFETs in the semiconductor device manufactured by the manufacturing method of Embodiment 5.

Consequently, in the semiconductor device manufactured by the manufacturing method of Embodiment 5, current driving is increased in both the P-type MISFET and the N-type MISFET.

What is claimed is:

1. A MISFET covered with an insulating film which generates stress, the MISFET comprising:
a gate insulating film disposed on a semiconductor substrate;
a gate electrode disposed on the gate insulating film, the gate electrode including a polysilicon portion and a silicide portion;
a source disposed adjacent to one side of the gate electrode; and
a drain disposed adjacent to the other side of the gate electrode,
wherein a ratio of length in a height direction of the polysilicon portion to length in a height direction of the silicide portion is determined depending on a strain for enhancing the driving capability of the MISFET, the strain being generated on the basis of the stress generated by the insulating film through the gate electrode in a channel region of the MISFET under the gate electrode.

2. The MISFET according to claim 1, wherein, when the stress generated by the insulating film is tensile stress and the MISFET is an N-type MISFET, the silicide has a higher Young's modulus than the polysilicon, and the ratio is in a range of 0.5 to 0.8.

3. The MISFET according to claim 1, wherein, when the stress generated by the insulating film is tensile stress and the MISFET is a P-type MISFET, the silicide has a higher Young's modulus than the polysilicon, and the ratio is in a range of 0.6 to 0.9.

4. A semiconductor device comprising:
an N-type MISFET covered with an insulating film which generates tensile stress, a gate electrode of the N-type MISFET including a polysilicon portion and a silicide portion, Young's modulus of a silicide in the silicide portion being higher than Young's modulus of a polysilicon in the polysilicon portion, a ratio of length in a height direction of the polysilicon portion to length in a height direction of the silicide portion being in a range of 0.5 to 0.8; and
a P-type MISFET covered with an insulating film which generates tensile stress, a gate electrode of the P-type MISFET including a polysilicon portion and a silicide portion, Young's modulus of a silicide in the silicide portion being higher than Young's modulus of a polysilicon in the polysilicon portion, a ratio of length in a height direction of the polysilicon portion to length in a height direction of the silicide portion being in a range of 0.6 to 0.9.

5. The semiconductor according to claim 4, wherein a silicide in the silicide portion is nickel silicide or titanium silicide.

6. The MISFET according to claim 1, wherein, when the stress generated by the insulating film is compressive stress and the MISFET is a P-type MISFET, the silicide has a lower Young's modulus than the polysilicon, and the ratio is in a range of 0.6 to 0.9.

7. The MISFET according to claim 1, wherein, when the stress generated by the insulating film is compressive stress and the MISFET is an N-type MISFET, the silicide has a lower Young's modulus than the polysilicon, and the ratio is in a range of 0.6 to 0.9.

8. A semiconductor device comprising:
an N-type MISFET covered with an insulating film which generates compressive stress, a gate electrode of the N-type MISFET including a polysilicon portion and a silicide portion, Young's modulus of a silicide in the silicide portion being lower than Young's modulus of a polysilicon in the polysilicon portion, and a ratio of length in a height direction of the polysilicon portion to length in a height direction of the silicide portion being in a range of 0.6 to 0.9; and
a P-type MISFET covered with an insulating film which generates tensile stress, a gate electrode of the P-type MISFET including a polysilicon portion and a silicide portion, Young's modulus of a silicide in the silicide portion being lower than Young's modulus of a polysilicon in the polysilicon portion, a ratio of length in a height direction of the polysilicon portion to length in a height direction of the silicide portion being in a range of 0.6 to 0.9.

9. The semiconductor according to claim 8, wherein a silicide in the silicide portion is cobalt silicide.

10. A method for manufacturing a MISFET covered with an insulating film which generates stress, the method comprising:
forming a gate insulating film on a semiconductor substrate;
forming a polysilicon pattern on the gate insulating film;
forming a sidewall composed of an insulating material on a side surface of the polysilicon pattern;
forming a metal layer on the polysilicon pattern; and
forming a gate electrode by allowing a metal constituting the metal layer to react with polysilicon constituting the polysilicon pattern to form a silicide, the gate electrode being composed of the polysilicon which remains unreacted and the silicide,
wherein a ratio of length in a height direction of the polysilicon portion to length in a height direction of the silicide portion is determined depending on a strain for enhancing the driving capability of the MISFET, the strain being generated on the basis of the stress generated by the insulating film through the gate electrode in a channel region of the MISFET under the gate electrode.

11. A method for manufacturing a semiconductor device provided with an N-type MISFET having a first gate electrode and a P-type MISFET having a second gate electrode formed on a principal surface of a semiconductor, the N-type MISFET and the P-type MISFET being covered with an insulating film which generates stress, the method comprising:
forming a gate insulating film on a semiconductor substrate;
forming a first polysilicon pattern and a second polysilicon pattern on the gate insulating film;
forming a sidewall composed of an insulating material on a side surface of each of the first polysilicon pattern and the second polysilicon pattern;
forming a metal layer on the first polysilicon pattern and the second polysilicon pattern; and
forming a first gate electrode and a second electrode by allowing a metal constituting the metal layer to react with polysilicon constituting the first polysilicon pattern and the second polysilicon pattern to form a silicide, the first gate electrode and the second gate electrode being composed of the polysilicon which remains unreacted and the silicide,
wherein a ratio of length in a height direction of the polysilicon portion to length in a height direction of the silicide portion in the first gate electrode is different from a ratio of length in a height direction of the polysilicon portion to length in a height direction of the silicide portion in the second gate electrode.

12. The method for manufacturing the semiconductor device according to claim 11, further comprising:
setting the height of the second polysilicon pattern smaller than the height of the first polysilicon pattern.

13. The method for manufacturing the semiconductor device according to claim 11, wherein, when the stress is tensile stress, the silicide has a higher Young's modulus than the polysilicon, the ratio between the polysilicon and the silicide in the first gate electrode is in a range of 0.6 to 0.7, and the ratio between the polysilicon and the silicide in the second gate electrode is in a range of 0.8 to 0.9.

14. The method for manufacturing the semiconductor device according to claim 11, wherein, when the stress is compressive stress, the silicide has a lower Young's modulus than the polysilicon, the ratio between the polysilicon and the silicide in the first gate electrode is in a range of 0.5 to 0.6, and the ratio between the polysilicon and the silicide in the second gate electrode is in a range of 0.8 to 0.9.
